(19) United States
(12) Patent Application Publication
(10) Pub. No.: US 2024/0365517 A1
(43) Pub. Date: Oct. 31, 2024

(54) DATA CENTER AND PHASE CHANGE COOLANT DISTRIBUTION UNIT THEREOF

(71) Applicant: INDUSTRIAL TECHNOLOGY RESEARCH INSTITUTE, Hsinchu (TW)

(72) Inventors: Heng-Chieh CHIEN, New Taipei City (TW); Shu-Jung YANG, New Taipei City (TW); Chih-Yao WANG, Zhubei City (TW)

(73) Assignee: INDUSTRIAL TECHNOLOGY RESEARCH INSTITUTE, Hsinchu (TW)

(21) Appl. No.: 18/648,302

(22) Filed: Apr. 26, 2024

Related U.S. Application Data
(60) Provisional application No. 63/462,494, filed on Apr. 27, 2023.

(30) Foreign Application Priority Data
Jan. 2, 2024 (TW) 113100019

(51) Int. Cl. H05K 7/20

(52) U.S. Cl. CPC H05K 7/20818; H05K 7/20327

(57) ABSTRACT

A phase change coolant distribution unit includes a heat-exchanging chamber, a low-position heat-exchanging tube, a high-position heat-exchanging tube and a phase change fluid. The low-position heat-exchanging tube is disposed through the heat-exchanging chamber, and at least one portion thereof is located in the heat-exchanging chamber. The high-position heat-exchanging tube is disposed through the heat-exchanging chamber, and at least one portion thereof is located in the heat-exchanging chamber. The phase change fluid is disposed in the heat-exchanging chamber. A data center includes a server rack, the phase change coolant distribution unit, a heat-source end working fluid and a heat-source pump. The heat-source end working fluid is disposed in the low-position heat-exchanging tube and a heat-source chamber of the server rack. The heat-source pump is disposed between the heat-source chamber and the low-position heat-exchanging tube to drive the heat-source end working fluid to flow.

This non-provisional application claims priority under 35 U.S.C. § 119(a) on provisional application No. 63/462,494 filed in U.S.A. on Apr. 27, 2023 and patent application No. 113100019 filed in Taiwan, R.O.C. on Jan. 2, 2024, the entire contents of which are hereby incorporated by reference.

### TECHNICAL FIELD

The disclosure relates to a data center and a phase change coolant distribution unit thereof.

### BACKGROUND

In recent years, as the amount of data required to be processed has increased, the number of servers included in the data center has increased, and heat generated by each server has increased. Therefore, a cooling system is needed to reduce the temperature of each server to facilitate the operation of each server.

In general, the cooling system for cooling servers includes a server rack, a heat-source-end fluid, a water-cooling tower, a cooling-end fluid and a heat exchanger. After the heat-source-end fluid absorbs heat generated by the servers in the server rack, the heat-source-end fluid flows to the heat exchanger to perform heat exchange with the cooling-end fluid from the water-cooling tower. In order to increase the efficiency of heat exchange, dense pipes with large surface areas used for heat exchange.

However, those pipes will increase the flow resistance of the fluid, which requires to use a pump with greater horsepower to drive the fluid, thereby consuming more energy.

### SUMMARY

One embodiment of the disclosure provides a phase change coolant distribution unit, including a heat-exchanging chamber, a low-position heat-exchanging tube, a high-position heat-exchanging tube and a phase change fluid. The low-position heat-exchanging tube is disposed through the heat-exchanging chamber. At least one portion of the low-position heat-exchanging tube is located in the heat-exchanging chamber. The high-position heat-exchanging tube is disposed through the heat-exchanging chamber. At least one portion of the high-position heat-exchanging tube is located in the heat-exchanging chamber. A position of the high-position heat-exchanging tube is higher than a position of the low-position heat-exchanging tube. The phase change fluid is disposed in the heat-exchanging chamber.

Another embodiment of the disclosure provides a data center, including a server rack, the said phase change coolant distribution unit, a heat-source end working fluid, a heat-source pump and a water-cooling tower. The server rack includes a heat-source chamber and a plurality of heat sources. The heat sources are disposed in the heat-source chamber. The heat-source end working fluid is disposed in the low-position heat-exchanging tube and the heat-source chamber. The heat-source pump is disposed between the heat-source chamber and the low-position heat-exchanging tube. The heat-source pump is configured to drive the heat-source end working fluid to flow. The water-cooling tower is connected with the high-position heat-exchanging tube.

Another embodiment of the disclosure provides a data center, including a server rack, the said phase change coolant distribution unit, a heat-source end working fluid and a heat-source pump. The server rack includes a heat-source chamber and a plurality of heat sources. The heat sources are disposed in the heat-source chamber. In the phase change coolant distribution unit, the high-position heat-exchanging tube is a heat pipe. An evaporation end of the heat pipe is disposed in the heat-exchanging chamber. A condensation end of the heat pipe is disposed outside the heat-exchanging chamber. The heat-source end working fluid is disposed in the low-position heat-exchanging tube and the heat-source chamber. The heat-source pump is disposed between the heat-source chamber and the low-position heat-exchanging tube. The heat-source pump is configured to drive the heat-source end working fluid to flow.

The above descriptions in the summary and the following detailed descriptions are used to demonstrate and explain the spirit and principle of the disclosure and provide a further explanation of the scope of claims of the disclosure.

### BRIEF DESCRIPTION OF THE DRAWINGS

The disclosure will become better understood from the detailed description given hereinbelow and the accompanying drawings which are given by way of illustration only and thus are not intending to limit the disclosure and wherein:

FIG. 1 is a schematic view of a data center according to one embodiment of the disclosure;

FIG. 2 is a cross-sectional view of a phase change coolant distribution unit in FIG. 1;

FIG. 3 is a cross-sectional views of a phase change coolant distribution unit according to another embodiment of the disclosure;

FIG. 4 is a cross-sectional views of a phase change coolant distribution unit according to another embodiment of the disclosure;

FIG. 5 is a schematic view of a data center according to another embodiment of the disclosure;

FIG. 6 is a cross-sectional views of the phase change coolant distribution unit in FIG. 5;

FIG. 7 is a cross-sectional views of a phase change coolant distribution unit according to another embodiment of the disclosure;

FIG. 8 is a cross-sectional views of a phase change coolant distribution unit according to another embodiment of the disclosure;

FIG. 9 is a schematic view of a data center according to another embodiment of the disclosure; and

FIG. 10 is a cross-sectional views of the phase change coolant distribution unit in FIG. 9.

### DETAILED DESCRIPTION

Features and advantages of embodiments of the disclosure are described in the following detailed description, it allows the person skilled in the art to understand the technical contents of the embodiments of the disclosure and implement them, and the person skilled in the art can easily comprehend the purposes of the advantages of the disclosure. The following embodiments are further illustrating the perspective of the disclosure, but not intending to limit the disclosure.

The drawings may not be drawn to actual size or scale, some exaggerations may be necessary in order to emphasize basic structural relationships, while some are simplified for clarity of understanding, but the disclosure is not limited thereto. It is allowed to have various adjustments under the spirit of the disclosure. In addition, the spatially relative terms, such as “up”, “top”, “above”, “down”, “low”, “left”, “right”, “front”, “rear”, and “back” and the like, may be used herein for ease of description to describe the relationship of one element or feature to another element(s) of feature(s) as illustrated in the drawings. It will be understood that the spatially relative terms are intended to encompass orientations of the element or feature but not intended to limit the disclosure.

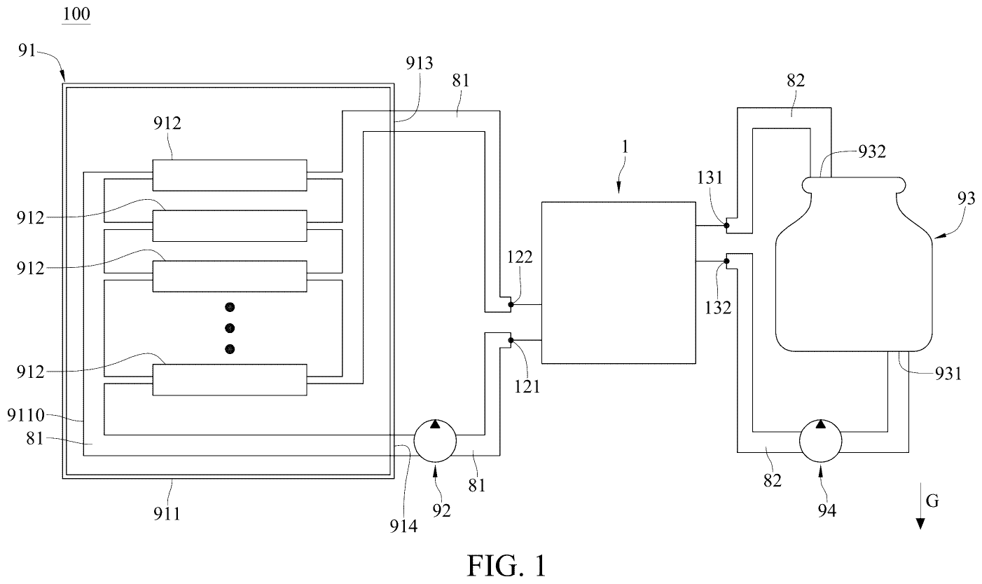

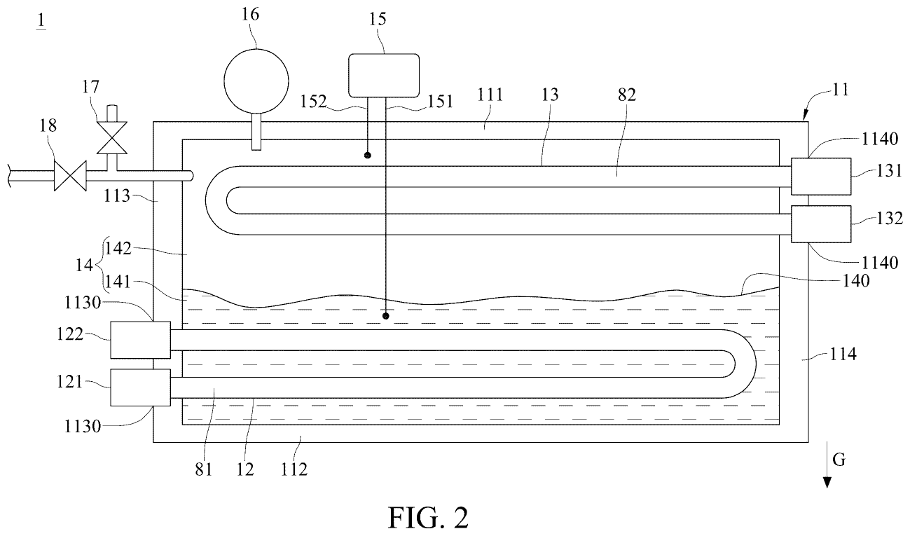

Please refer to FIG. 1 and FIG. 2. FIG. 1 is a schematic view of a data center according to one embodiment of the disclosure. FIG. 2 is a cross-sectional view of a phase change coolant distribution unit in FIG. 1.

This disclosure is to provide a data center and a phase change coolant distribution unit thereof, which may prevent a fluid from suffering excessive flow resistance.

As shown in FIG. 1, a data center 100 includes a server rack 91, a heat-source pump 92, a phase change coolant distribution unit 1, a water-cooling tower 93, a cooling pump 94, a heat-source end working fluid 81 and a cooling end working fluid 82. The server rack 91 includes a heat-source chamber 911 and a plurality of heat sources 912. The heat sources 912 are disposed in the heat-source chamber 911. The heat sources 912 may be an electronic device in high temperature during operation, such as a server. The heat-source chamber 911 has an outlet 913 and an inlet 914. The heat-source end working fluid 81 is disposed in the heat-source chamber 911, may flow into the heat-source chamber 911 through the inlet 914, and may flow out of the heat-source chamber 911 through the outlet 913.

In this embodiment, the server rack 91 may include a pipeline network 9110. The pipeline network 9110 is disposed in the heat-source chamber 911, and is disposed to perform heat exchange with the heat source 912. The pipeline network 9110 is connected to the inlet 914 and the outlet 913. The heat-source end working fluid 81, which flows into the pipeline network 9110 from the inlet 914, may absorb heat generated by the heat sources 912 through the pipeline network 9110, and then flow out of the heat-source chamber 911 from the outlet 913. The heat-source end working fluid 81, which flows out of the heat-source chamber 911 from the outlet 913, may flow to the phase change coolant distribution unit 1 so as to perform heat exchange with the cooling end working fluid 82 supplied by the water-cooling tower 93 and the cooling pump 94. Then, the cooled heat-source end working fluid 81 flows back into the pipeline network 9110 in the heat-source chamber 911 from the inlet 914. However, the disclosure is not limited thereto.

In other embodiments, the pipeline network 9110 may be omitted, and the heat sources 912 may be directly immersed in the heat-source end working fluid 81 filled in the heat-source chamber 911. In such case, the heat-source end working fluid 81, which flows into the heat-source chamber 911 from the inlet 914, may directly absorb heat generated by the heat sources 912. Then, the heat-source end working fluid 81 flows out of the heat-source chamber 911 from the outlet 913, and then enter into the phase change coolant distribution unit 1 for performing heat exchange with the cooling end working fluid 82. Then, the heat-source end working fluid 81 flows back into the heat-source chamber 911 from the inlet 914.

As shown in FIG. 2, the phase change coolant distribution unit 1 includes a heat-exchanging chamber 11, a low-position heat-exchanging tube 12, a high-position heat-exchanging tube 13 and a phase change fluid 14.

The heat-exchanging chamber 11 may have a top wall 111, a bottom wall 112 and two side walls 113 and 114 located opposite to each other. The side wall 113 has two openings 1130 near the bottom wall 112. The side wall 114 has two openings 1140 near the top wall 111.

The low-position heat-exchanging tube 12 passes through the two openings 1130 and is disposed through the heat-exchanging chamber 11. The low-position heat-exchanging tube 12 has an outlet 121 and an inlet 122. The low-position heat-exchanging tube 12 may be a non-dense pipeline, such as a U-shaped tube or a coiled tube. The inlet 122 and the outlet 121 of the low-position heat-exchanging tube 12 are located outside the heat-exchanging chamber 11, and the rest part of the low-position heat-exchanging tube 12 is almost located in the heat-exchanging chamber 11.

The high-position heat-exchanging tube 13 passes through the two openings 1140 and is disposed through the heat-exchanging chamber 11. The high-position heat-exchanging tube 13 has an outlet 131 and an inlet 132. The high-position heat-exchanging tube 13 may be a non-dense pipeline, such as a U-shaped tube or a bent tube. The inlet 132 and the outlet 131 of the high-position heat-exchanging tube 13 are located outside the heat-exchanging chamber 11, and the rest part of the high-position heat-exchanging tube 13 is almost located in the heat-exchanging chamber 11. In a gravity direction G, a position of the high-position heat-exchanging tube 13 is higher than a position of the low-position heat-exchanging tube 12.

The phase change fluid 14 is disposed in the heat-exchanging chamber 11 and located outside the low-position heat-exchanging tube 12 and the high-position heat-exchanging tube 13. The phase change fluid 14 includes a liquid-phase portion 141 and a vapor-phase portion 142 and has a liquid surface 140. In this embodiment, the liquid surface 140 of the phase change fluid 14 is located between the low-position heat-exchanging tube 12 and the high-position heat-exchanging tube 13. In other words, the low-position heat-exchanging tube 12 is located under the liquid surface 140 and is entirely immersed in the liquid-phase portion 141 of the phase change fluid 14. The high-position heat-exchanging tube 13 is located in the vapor-phase portion 142 of the phase change fluid 14. The phase change fluid 14 flows into neither the low-position heat-exchanging tube 12 nor the high-position heat-exchanging tube 13.

In addition, the phase change coolant distribution unit 1 may further include a thermometer 15, a pressure gauge 16, a pressure relief valve 17 and a vacuum valve 18. The thermometer 15 is disposed at the top wall 111 the heat-exchanging chamber 11. The thermometer 15 is to measure the temperature of the phase change fluid 14. In this embodiment, the thermometer 15 has two probe 151 and 152. One end of probe 151 extends into the liquid-phase portion 141 of the phase change fluid 14 to measure the temperature of the liquid-phase portion 141. One end of the probe 152 extends into the vapor-phase portion 142 of the phase change fluid 14 to measure the temperature of the vapor-phase portion 142. However, the disclosure is not limited thereto. In other embodiments, two thermometers 15 may be provided to be disposed at the top wall 111 and the bottom wall 112 of the heat-exchanging chamber 11, respectively. For example, the thermometer 15 disposed at the bottom wall 112 is to measure the temperature of the liquid-phase portion 141, and the thermometer 15 disposed at the top wall 111 is to measure the temperature of the vapor-phase portion 142.

In this embodiment, the pressure gauge 16 is disposed at the top wall 111 of the heat-exchanging chamber 11. The pressure gauge 16 is to measure the pressure of the vapor-phase portion 142 of the phase change fluid 14. The pressure relief valve 17 and the vacuum valve 18 are disposed at a portion of the side wall 113 of the heat-exchanging chamber 11 near the top wall 111 and may directly communicate with atmosphere or may be connected to a storage tank (not shown) for the phase change fluid 14. The pressure relief valve 17 may be opened when the pressure gauge 16 measures that the pressure of the vapor-phase portion 142 of the phase change fluid 14 is too high, so as to reduce the pressure of the vapor-phase portion 142 of the phase change fluid 14. The vacuum valve 18 may be connected to a vacuum pump (not shown). In order to further reduce the boiling temperature of the phase change fluid 14, the vacuum valve 18 may be turned on to extract an internal air from the heat-exchanging chamber 11 before operation.

As shown in FIG. 1 and FIG. 2, the inlet 122 of the low-position heat-exchanging tube 12 of the phase change coolant distribution unit 1 is connected with the outlet 913 of the heat-source chamber 911 of the server rack 91. The heat-source pump 92 is disposed between the outlet 121 of the low-position heat-exchanging tube 12 and the inlet 914 of the heat-source chamber 911. The outlet 121 of the low-position heat-exchanging tube 12 is connected with the inlet 914 of the heat-source chamber 911. The heat-source end working fluid 81 is disposed in the heat-source chamber 911 and the low-position heat-exchanging tube 12. The heat-source pump 92 is configured to drive the heat-source end working fluid 81 to circularly flow between the low-position heat-exchanging tube 12 and the heat-source chamber 911. Since both of the low-position heat-exchanging tube 12 and the heat-source chamber 911 are non-dense pipelines, the heat-source pump 92 may be a pump with relatively small horsepower for driving a circulation flow of the heat-source end working fluid 81. The position of the heat-source pump 92 is not limited in this disclosure. In other embodiments, the heat-source pump 92 may be disposed between the inlet 122 of the low-position heat-exchanging tube 12 and the outlet 913 of the heat-source chamber 911 as required, or may be disposed at other positions where the heat-source end working fluid 81 may be driven to circularly flow between the low-position heat-exchanging tube 12 and the heat-source chamber 911.

In this embodiment, the water-cooling tower 93 has an inlet 932 and an outlet 931. The inlet 932 of the water-cooling tower 93 is connected with the outlet 131 of the high-position heat-exchanging tube 13 of the phase change coolant distribution unit 1. The cooling pump 94 is disposed between the outlet 931 of the water-cooling tower 93 and the inlet 132 of the high-position heat-exchanging tube 13. The inlet 932 of the water-cooling tower 93 is connected with the outlet 131 of the high-position heat-exchanging tube 13. The cooling end working fluid 82 is disposed in the water-cooling tower 93 and the high-position heat-exchanging tube 13. The cooling pump 94 is configured to drive the cooling end working fluid 82 to circularly flow between the high-position heat-exchanging tube 13 and the water-cooling tower 93. Since both of the high-position heat-exchanging tube 13 and the water-cooling tower 93 are non-dense pipelines, the cooling pump 94 may be a pump with relatively small horsepower for driving a circulation flow of the cooling end working fluid 82. The position of the cooling pump 94 is not limited in this disclosure. In other embodiments, the cooling pump 94 may be disposed between the outlet 131 of the high-position heat-exchanging tube 13 and the inlet 932 of the water-cooling tower 93, or may be disposed at other positions where the cooling end working fluid 82 may be driven to circularly flow between the high-position heat-exchanging tube 13 and the water-cooling tower 93.

In this embodiment, the boiling point of the phase change fluid 14 may be lower than the boiling point of the heat-source end working fluid 81, and the boiling point of the phase change fluid 14 may be lower than the boiling point of the cooling end working fluid 82. The phase change fluid 14 may be water, methanol, acetone, ionic fluid or dielectric fluid.

As shown in FIG. 1 and FIG. 2, the heat-source end working fluid 81 absorbs heat generated by the heat sources 912, and then flows into the low-position heat-exchanging tube 12 through the outlet 913 of the heat-source chamber 911 and the inlet 122 of the low-position heat-exchanging tube 12. The heat-source end working fluid 81 in the low-position heat-exchanging tube 12 performs heat exchange with the liquid-phase portion 141 of the phase change fluid 14, and then flows into the heat-source chamber 911 through the outlet 121 of the low-position heat-exchanging tube 12 and the inlet 914 of the heat-source chamber 911.

When the liquid-phase portion 141 of the phase change fluid 14 absorbs enough heat, it will vaporize into a vapor phase so as to become the vapor-phase portion 142, and then performs heat exchange with the cooling end working fluid 82 in the high-position heat-exchanging tube 13. After the vapor-phase portion 142 performs heat exchange with the cooling end working fluid 82 from the cooling pump 94 and releases enough heat, it will condense into a liquid phase on the surface of the high-position heat-exchanging tube 13 and drip to the liquid-phase portion 141.

The cooling end working fluid 82 absorbs the heat from the vapor-phase portion 142 and then flows into the water-cooling tower 93 through the outlet 131 of the high-position heat-exchanging tube 13 and the inlet 932 of the water-cooling tower 93. After the cooling end working fluid 82 is cooled in the water-cooling tower 93, the cooled cooling end working fluid 82 flows back into the high-position heat-exchanging tube 13 through the outlet 931 of the water-cooling tower 93 and the inlet 132 of the high-position heat-exchanging tube 13 by the driving of the cooling pump 94.

Through the phase change of the phase change fluid 14 between the liquid-phase portion 141 and the vapor-phase portion 142, the increase of flow resistance caused by the increase in the fluid flow path caused by the increase of the heat-exchange surface area may be avoided, and thus the heat-source pump 92 and the cooling pump 94 with a relatively small horsepower may be used to provide the circulating flow of the heat-source end working fluid 81 and the cooling end working fluid 82. Furthermore, since the boiling point of the heat-source end working fluid 81 is higher than the boiling point of the phase change fluid 14, the situation, in which the heat-source end working fluid 81 is overheated and vaporized while the phase change fluid 14 is still not activated during operation, will not occur easily. In addition, when maintaining the heat sources 912 such as a server, even if the heat-source chamber 911 is opened, it is uneasy for the heat-source end working fluid 81 to volatilize into vapor and leak into the atmosphere.

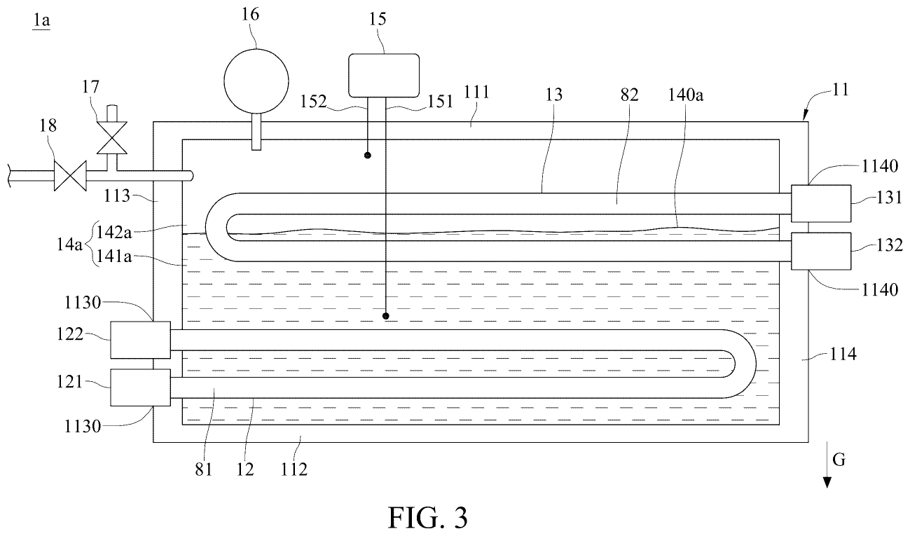

Please refer to FIG. 3. FIG. 3 is a cross-sectional view of a phase change coolant distribution unit according to another embodiment of the disclosure. As shown in FIG. 3, a phase change coolant distribution unit 1a is similar to the phase change coolant distribution unit 1 shown in FIG. 2, and repeated descriptions are omitted hereinafter.

In this embodiment, a phase change fluid 14a includes a liquid-phase portion 141a and a vapor-phase portion 142a and has a liquid surface 140a. The high-position heat-exchanging tube 13 passes through the liquid surface 140a of the phase change fluid 14a. In other words, the low-position heat-exchanging tube 12 is entirely immersed in the liquid-phase portion 141a of the phase change fluid 14a. One portion of the high-position heat-exchanging tube 13 is located in the liquid-phase portion 141a, and the other portion is located in the vapor-phase portion 142a.

The liquid-phase portion 141a of the phase change fluid 14a may perform heat exchange with the heat-source end working fluid 81 in the low-position heat-exchanging tube 12 and the cooling end working fluid 82 in the high-position heat-exchanging tube 13. The vapor-phase portion 142a of the phase change fluid 14a may perform heat exchange with the cooling end working fluid 82 in the high-position heat-exchanging tube 13. When the liquid-phase portion 141a absorbs enough heat, a part of the liquid-phase portion 141a will nucleate and boil, the nucleated liquid will rise and transfer the heat to the high-position heat-exchanging tube 13, and another part of the liquid-phase portion 141a will vaporize into a vapor phase so as to become the vapor-phase portion 142a. When the vapor-phase portion 142a releases enough heat, the vapor-phase portion 142a condenses into a liquid phase and drips to become the liquid-phase portion 141a.

Furthermore, a user may replace the phase change coolant distribution unit 1 of the data center 100 in FIG. 1 with the phase change coolant distribution unit 1a in FIG. 3 for application.

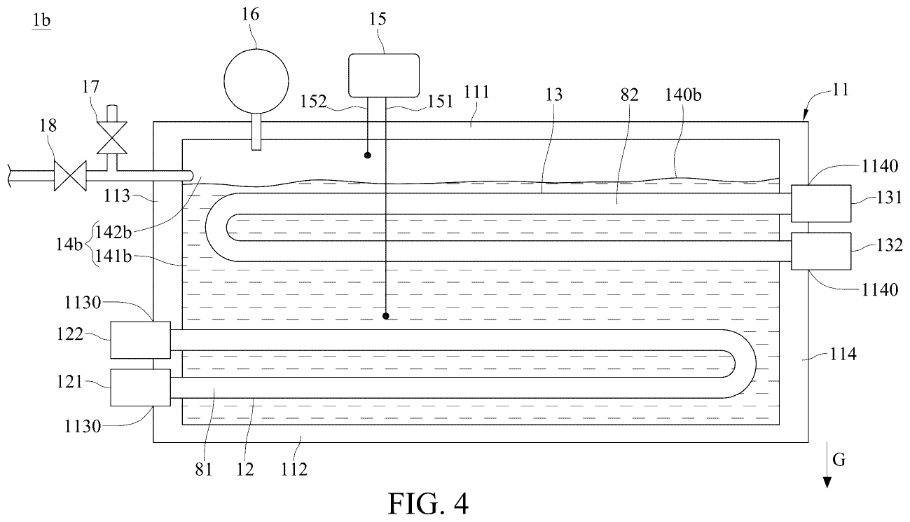

Please refer to FIG. 4. FIG. 4 is a cross-sectional view of a phase change coolant distribution unit according to another embodiment of the disclosure. As shown in FIG. 4, a phase change coolant distribution unit 1b is similar to the phase change coolant distribution unit 1 shown in FIG. 2, and repeated descriptions are omitted hereinafter.

In this embodiment, a phase change fluid 14b includes a liquid-phase portion 141b and a vapor-phase portion 142b and has a liquid surface 140b. Both of the low-position heat-exchanging tube 12 and the high-position heat-exchanging tube 13 are located under the liquid surface 140b of the phase change fluid 14b. In other words, both of the low-position heat-exchanging tube 12 and the high-position heat-exchanging tube 13 are entirely immersed in the liquid-phase portion 141b of the phase change fluid 14b.

The liquid-phase portion 141b of the phase change fluid 14b may perform heat exchange with the heat-source end working fluid 81 in the low-position heat-exchanging tube 12 and the cooling end working fluid 82 in the high-position heat-exchanging tube 13. When the liquid-phase portion 141b absorbs enough heat, it will vaporize into a vapor phase so as to become the vapor-phase portion 142b. When the vapor-phase portion 142b releases enough heat, it will condense into a liquid phase and drip to become the liquid-phase portion 141b.

Furthermore, a user may replace the phase change coolant distribution unit 1 of the data center 100 in FIG. 1 with the phase change coolant distribution unit 1b in FIG. 4 for application.

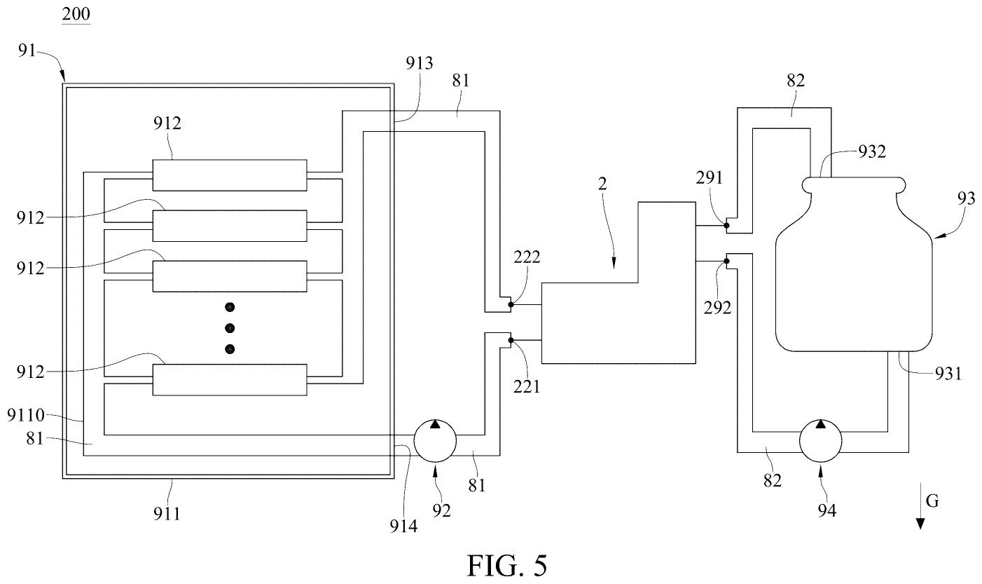

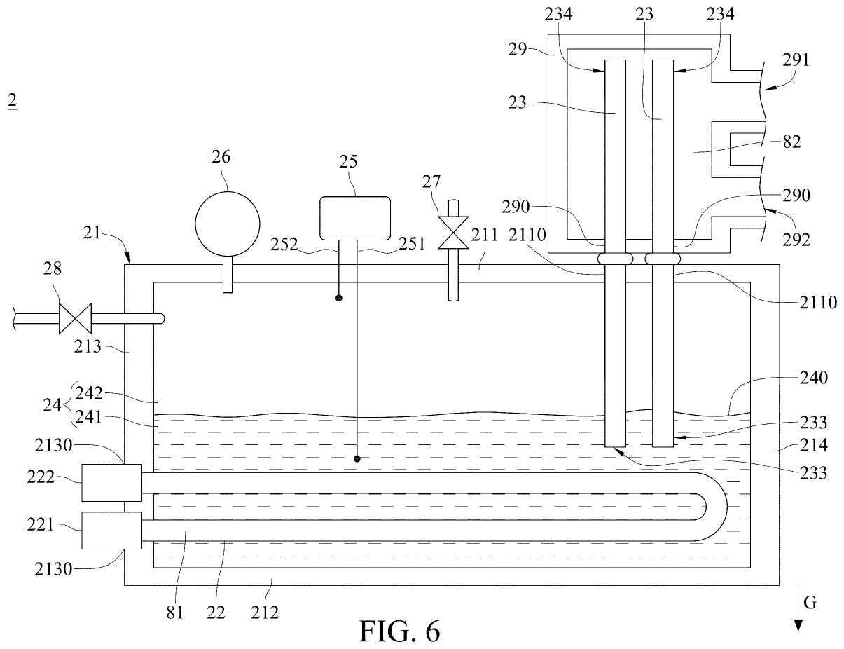

Please refer to FIG. 5 and FIG. 6. FIG. 5 is a schematic view of a data center according to another embodiment of the disclosure. FIG. 6 is a cross-sectional view of the phase change coolant distribution unit in FIG. 5. In this embodiment, a data center 200 is similar to the data center 100 shown in FIG. 1, and a phase change coolant distribution unit 2 is similar to the phase change coolant distribution unit 1 shown in FIG. 2. Similar elements will be labeled with similar symbols, and repeated descriptions will be omitted appropriately hereinafter.

As shown in FIG. 5, in this embodiment, the data center 200 includes a server rack 91, a heat-source pump 92, a phase change coolant distribution unit 2, a water-cooling tower 93, a cooling pump 94, the heat-source end working fluid 81 and the cooling end working fluid 82.

As shown in FIG. 6, in this embodiment, the phase change coolant distribution unit 2 includes a heat-exchanging chamber 21, a low-position heat-exchanging tube 22, two high-position heat-exchanging tubes 23, a phase change fluid 24, a thermometer 25, a pressure gauge 26, a pressure relief valve 27, a vacuum valve 28 and a cooling chamber 29.

In the heat-exchanging chamber 21, a side wall 213 has two openings 2130 near a bottom wall 212, and a top wall 211 has two openings 2110 near a side wall 214. The low-position heat-exchanging tube 22 passes through the two openings 2130 and is disposed through the heat-exchanging chamber 21. An outlet 221 and an inlet 222 of the low-position heat-exchanging tube 22 are located outside the heat-exchanging chamber 21, and the rest part of the low-position heat-exchanging tube 22 is almost located in the heat-exchanging chamber 21.

The high-position heat-exchanging tubes 23 are heat pipes. The cooling chamber 29 is disposed outside the heat-exchanging chamber 21. The cooling chamber 29 has two openings 290, an outlet 291 and an inlet 292. The high-position heat-exchanging tubes 23 is disposed through the openings 2110 of the heat-exchanging chamber 21 and the openings 290 of the cooling chamber 29. Each of the high-position heat-exchanging tubes 23 has an evaporation end 233 and a condensation end 234, where the evaporation end 233 is located in the heat-exchanging chamber 21, and the condensation end 234 is located outside the heat-exchanging chamber 21 and in the cooling chamber 29. In the gravity direction G, positions of the high-position heat-exchanging tubes 23 are higher than a position of the low-position heat-exchanging tube 22.

In this embodiment, although the number of the high-position heat-exchanging tubes 23 is two, the disclosure is not limited thereto. In other embodiments, the number of the high-position heat-exchanging tubes may be one or more than two, and the number of the openings 2110 and the number of the openings 290 may be modified according to the number of the high-position heat-exchanging tubes 23. In addition, the high-position heat-exchanging tubes 23 may be made into a element with the same function as a heat pipe according to requirements, such as a vapor chamber, but the disclosure is not limited thereto.

In this embodiment, the high-position heat-exchanging tubes 23 pass through a liquid surface 240 of the phase change fluid 24. In other words, the low-position heat-exchanging tube 22 is entirely immersed in a liquid-phase portion 241 of the phase change fluid 24. In the heat-exchanging chamber 21, one portion of the high-position heat-exchanging tubes 23 is located in the liquid-phase portion 241, and the other portion is located in a vapor-phase portion 242.

The thermometer 25 is disposed at the top wall 211 of the heat-exchanging chamber 21. A probe 251 of the thermometer 25 is configured to measure the temperature of the liquid-phase portion 241, and a probe 252 is configured to measure the temperature of the vapor-phase portion 242. The pressure gauge 26 and the pressure relief valve 27 are disposed at the top wall 211. The vacuum valve 28 is disposed at the side wall 213 of the heat-exchanging chamber 21 near the top wall 211.

As shown in FIG. 5 and FIG. 6, the inlet 222 of the low-position heat-exchanging tube 22 is connected with the outlet 913 of the heat-source chamber 911 of the server rack 91. The heat-source pump 92 is disposed between the outlet 221 of the low-position heat-exchanging tube 22 and the inlet 914 of the heat-source chamber 911. The inlet 222 of the low-position heat-exchanging tube 22 is connected with the outlet 913 of the heat-source chamber 911. The heat-source end working fluid 81 is disposed in the heat-source chamber 911 and the low-position heat-exchanging tube 22. The inlet 932 of the water-cooling tower 93 is connected with the outlet 291 of the cooling chamber 29. The cooling pump 94 is disposed between the outlet 931 of the water-cooling tower 93 and the inlet 292 of the cooling chamber 29. The outlet 931 of the water-cooling tower 93 is connected with the inlet 292 of the cooling chamber 29. The cooling end working fluid 82 is disposed in the water-cooling tower 93 and the cooling chamber 29.

The liquid-phase portion 241 of the phase change fluid 24 may perform heat exchange with the heat-source end working fluid 81 in the low-position heat-exchanging tube 22 and the evaporation ends 233 of the high-position heat-exchanging tubes 23. The high-position heat-exchanging tubes 23 absorbs heat and quickly transfers the heat to the condensation ends 234 so as to perform heat exchange with the cooling end working fluid 82 from the cooling pump 94. When the liquid-phase portion 241 absorbs enough heat, the liquid-phase portion 241 will vaporize into a vapor phase so as to become the vapor-phase portion 242. The vapor-phase portion 242 contacts a surface of the high-position heat-exchanging tubes 23, which has been performed heat exchange and released heat in the cooling chamber 29, and then the vapor-phase portion 242 is condensed into a liquid phase and drips to become the liquid-phase portion 241.

In the cooling chamber 29, the cooling end working fluid 82 performs heat exchanges with the condensation ends 234 of the high-position heat-exchanging tubes 23 and then flows into the water-cooling tower 93 through the outlet 291 of the cooling chamber 29 and the inlet 932 of the water-cooling tower 93. After the cooling end working fluid 82 is cooled in the water-cooling tower 93, the cooled cooling end working fluid 82 flows back into the cooling chamber 29 through the outlet 931 of the water-cooling tower 93 and the inlet 292 of the cooling chamber 29 by the driving of the cooling pump 94.

In other embodiments, a user may install the phase change coolant distribution unit 2 in conjunction with the server rack 91 and the heat-source pump 92 for application, and the water-cooling tower 93, the cooling pump 94, the cooling end working fluid 82 and the cooling chamber 29 may be omitted. In such a case, through the condensation ends 234 of the high-position heat-exchanging tubes 23 in the cooling chamber 29 in a design mode such as conduction or convection, the heat is transferred to an atmosphere through the cooling chamber 29 in an air-cooling manner.

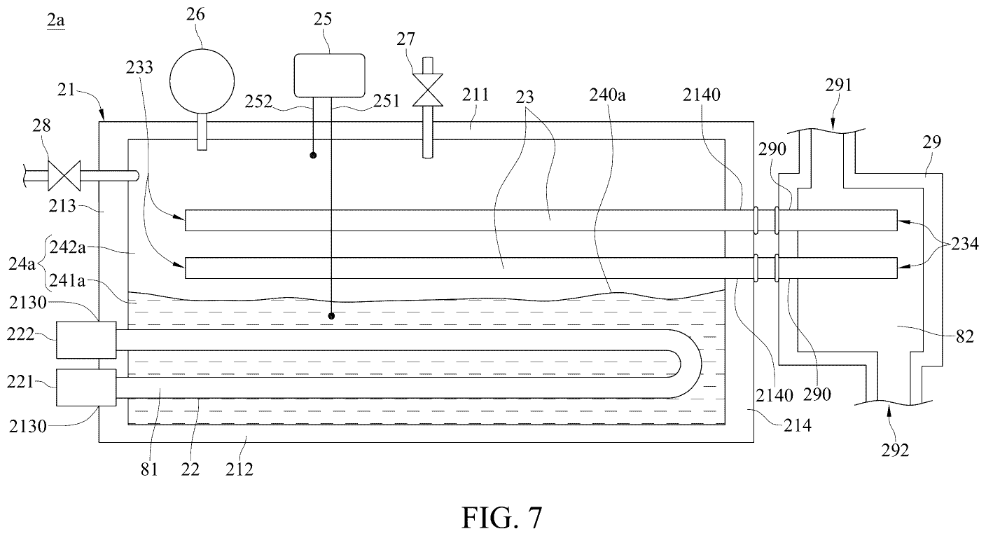

Please refer to FIG. 7. FIG. 7 is a cross-sectional view of a phase change coolant distribution unit according to another embodiment of the disclosure. As shown in FIG. 7, a phase change coolant distribution unit 2a is similar to the phase change coolant distribution unit 2 shown in FIG. 5, and repeated descriptions are omitted hereinafter.

In the heat-exchanging chamber 21 of this embodiment, the side wall 214 has two openings 2140 near the top wall 211. The high-position heat-exchanging tubes 23 are disposed through the openings 2140 of the heat-exchanging chamber 21 and the openings 290 of the cooling chamber 29.

A phase change fluid 24a includes a liquid-phase portion 241a and a vapor-phase portion 242a and has a liquid surface 240a. The liquid surface 240a is located between the low-position heat-exchanging tube 22 and the high-position heat-exchanging tubes 23. In other words, the low-position heat-exchanging tube 22 is located under the liquid surface 240a and is entirely immersed in the liquid-phase portion 241a. The high-position heat-exchanging tubes 23 is located in the vapor-phase portion 242a of the phase change fluid 24a.

The liquid-phase portion 241a of the phase change fluid 24a performs heat exchange with the heat-source end working fluid 81 in the low-position heat-exchanging tube 22. The vapor-phase portion 242a of the phase change fluid 24a perform heat exchange with the evaporation ends 233 of the high-position heat-exchanging tubes 23. The high-position heat-exchanging tubes 23 absorbs heat and quickly transfers the heat to the condensation ends 234 so as to perform heat exchange with the cooling end working fluid 82 from the cooling pump 94. When the liquid-phase portion 241a absorbs enough heat, the liquid-phase portion 241a will vaporize into a vapor phase so as to become the vapor-phase portion 242a. The vapor-phase portion 242a performs heat exchange with the high-position heat-exchanging tubes 23, which have released heat, is condensed into a liquid phase, and then drips to become the liquid-phase portion 241a.

Furthermore, a user may replace the phase change coolant distribution unit 2 of the data center 200 in FIG. 5 with the phase change coolant distribution unit 2a in FIG. 7 for application.

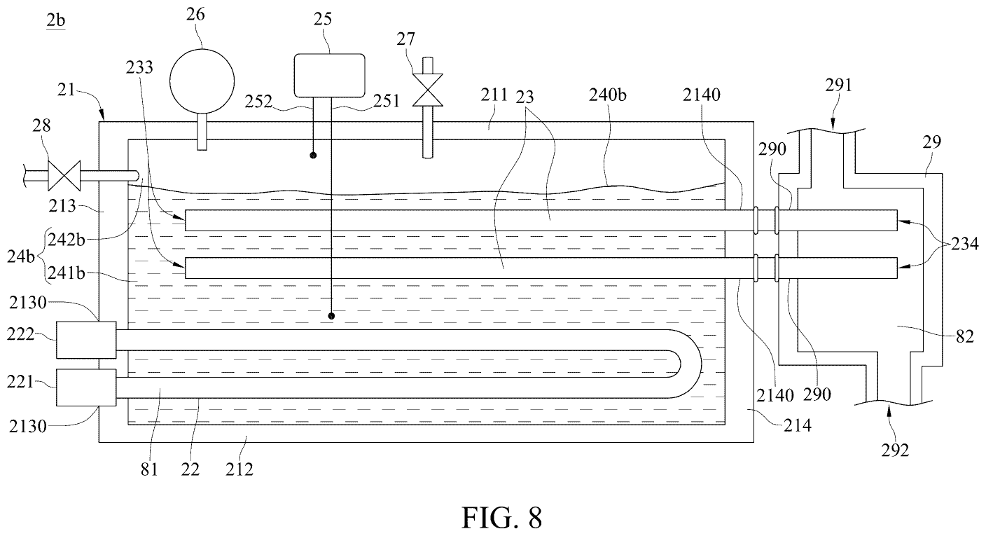

Please refer to FIG. 8. FIG. 8 is a cross-sectional view of a phase change coolant distribution unit according to another embodiment of the disclosure. As shown in FIG. 8, a phase change coolant distribution unit 2b is similar to the phase change coolant distribution unit 2a shown in FIG. 7, and repeated descriptions are omitted hereinafter.

In this embodiment, a phase change fluid 24b includes a liquid-phase portion 241b and a vapor-phase portion 242b and has a liquid surface 240b. In the heat-exchanging chamber 21, both of the low-position heat-exchanging tube 22 and the high-position heat-exchanging tubes 23 are located under the liquid surface 240b of the phase change fluid 24b. In other words, in the heat-exchanging chamber 21, both of the low-position heat-exchanging tube 22 and the high-position heat-exchanging tubes 23 are entirely immersed in the liquid-phase portion 241b of the phase change fluid 24b.

The liquid-phase portion 241b of the phase change fluid 24b performs heat exchange with the heat-source end working fluid 81 in the low-position heat-exchanging tube 22 and the evaporation end 233 of the high-position heat-exchanging tubes 23. When the liquid-phase portion 241b absorbs enough heat, a part of the liquid-phase portion 241b will nucleate and boil, the nucleated liquid will rise and transfer the heat to the high-position heat-exchanging tubes 23, and another part of the liquid-phase portion 241b will vaporize into a vapor phase so as to become the vapor-phase portion 242b. When the vapor-phase portion 242b performs heat exchange with an outside environment and releases enough heat, the vapor-phase portion 242b condenses into a liquid phase and drips to become the liquid-phase portion 241b.

Furthermore, a user may replace the phase change coolant distribution unit 2 of the data center 200 in FIG. 5 with the phase change coolant distribution unit 2b in FIG. 8 for application.

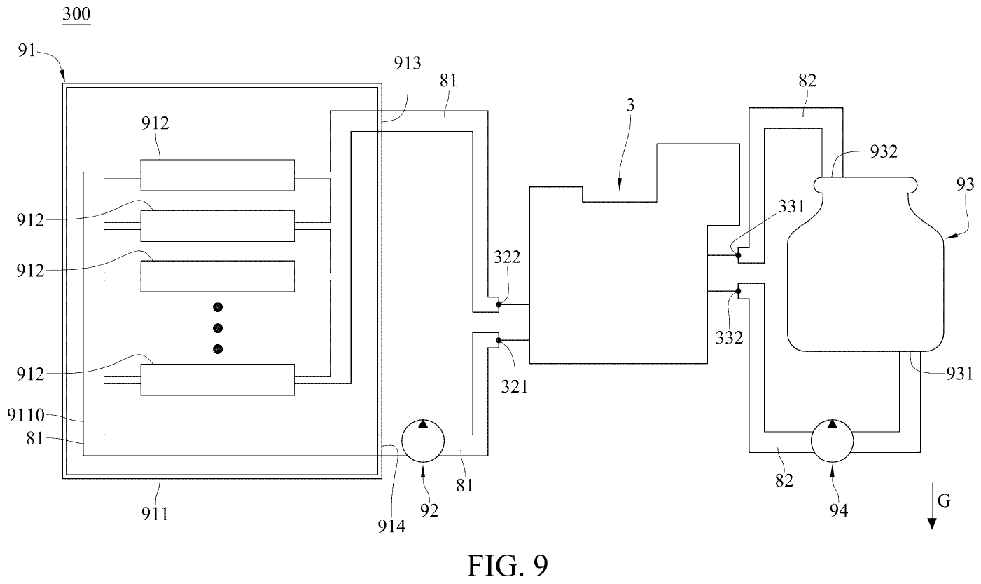

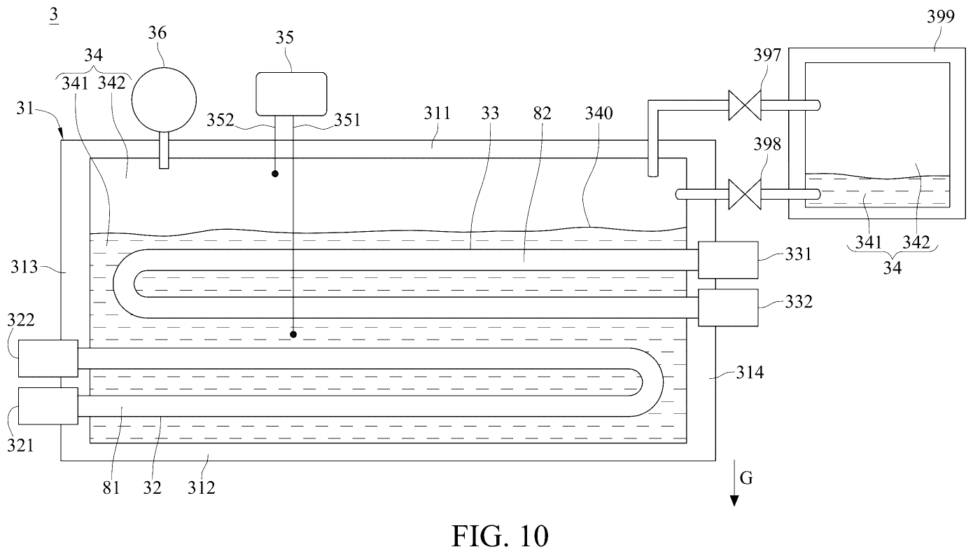

Please refer to FIG. 9 and FIG. 10. FIG. 9 is a schematic view of a data center according to another embodiment of the disclosure. FIG. 10 is a cross-sectional view of a phase change coolant distribution unit in FIG. 9. In this embodiment, a data center 300 is similar to the data center 100 shown in FIG. 1, a phase change coolant distribution unit 3 is similar to the phase change coolant distribution unit 1 shown in FIG. 2. Similar elements will be labeled with similar symbols, and repeated descriptions will be omitted appropriately hereinafter.

As shown in FIG. 9, in this embodiment, the data center 300 includes a server rack 91, a heat-source pump 92, a phase change coolant distribution unit 3, a water-cooling tower 93, a cooling pump 94, the heat-source end working fluid 81 and the cooling end working fluid 82.

As shown in FIG. 10, in this embodiment, the phase change coolant distribution unit 3 includes a heat-exchanging chamber 31, a low-position heat-exchanging tube 32, a high-position heat-exchanging tube 33, a phase change fluid 34, a thermometer 35, a pressure gauge 36, a vapor-phase valve 397, a liquid-phase valve 398 and a pressure relief tank 399.

The heat-exchanging chamber 31 may have a top wall 311, a bottom wall 312 and two side walls 313, 314 opposite to each other. The low-position heat-exchanging tube 32 is disposed through the heat-exchanging chamber 31. An inlet 322 and an outlet 321 of the low-position heat-exchanging tube 32 are located outside the heat-exchanging chamber 31, and the rest part of the low-position heat-exchanging tube 32 is almost located in the heat-exchanging chamber 31. The high-position heat-exchanging tube 33 is disposed through the heat-exchanging chamber 31. An inlet 332 and an outlet 331 of the high-position heat-exchanging tube 33 are located outside the heat-exchanging chamber 31, and the rest part of the high-position heat-exchanging tube 33 is almost located in the heat-exchanging chamber 31. In the gravity direction G, a position of the high-position heat-exchanging tube 33 is higher than a position of the low-position heat-exchanging tube 32.

The phase change fluid 34 includes a liquid-phase portion 341 and a vapor-phase portion 342 and has a liquid surface 340. In the heat-exchanging chamber 31, both of the low-position heat-exchanging tube 32 and the high-position heat-exchanging tube 33 are located under the liquid surface 340 of the phase change fluid 34. In other words, in the heat-exchanging chamber 31, both of the low-position heat-exchanging tube 32 and the high-position heat-exchanging tube 33 are entirely immersed in the liquid-phase portion 341 of the phase change fluid 34.

The thermometer 35 is disposed at the top wall 311 of the heat-exchanging chamber 31. A probe 351 of the thermometer 35 is configured to measure the temperature of the liquid-phase portion 341, a probe 352 is configured to measure the temperature of the vapor-phase portion 342. The pressure gauge 36 is disposed at the top wall 311.

The pressure relief tank 399 is disposed outside the heat-exchanging chamber 31. The vapor-phase valve 397 is disposed at the top wall 311 near the side wall 314. The vapor-phase valve 397 is connected to a relatively high position of the pressure relief tank 399. The liquid-phase valve 398 is disposed at the side wall 314 near the top wall 311. The liquid-phase valve 398 is connected to a relatively low position of the pressure relief tank 399.

In the heat-exchanging chamber 31, when the pressure of the vapor-phase portion 342 of the phase change fluid 34 measured by the pressure gauge 36 is too high, the vapor-phase valve 397 may be activated, and a part of the vapor-phase portion 342 of the phase change fluid 34 flows to the pressure relief tank 399 and then condenses into the liquid-phase portion 341. In the heat-exchanging chamber 31, if the liquid surface 340 is too low, the liquid-phase valve 398 may be opened and allow some of the liquid-phase portion 341 to flow back into the heat-exchanging chamber 31.

As shown in FIG. 9 and FIG. 10, the outlet 321 of the low-position heat-exchanging tube 32 is connected with the inlet 914 of the heat-source chamber 911 of the server rack 91. The heat-source pump 92 is disposed between the outlet 321 of the low-position heat-exchanging tube 32 and the inlet 914 of the heat-source chamber 911. The inlet 322 of the low-position heat-exchanging tube 32 is connected with the outlet 913 of the heat-source chamber 911. The heat-source end working fluid 81 is disposed in the heat-source chamber 911 and the low-position heat-exchanging tube 32. The inlet 932 of the water-cooling tower 93 is connected with the outlet 331 of the high-position heat-exchanging tube 33. The cooling pump 94 is disposed between the outlet 931 of the water-cooling tower 93 and the inlet 332 of the high-position heat-exchanging tube 33. The outlet 931 of the water-cooling tower 93 is connected with the inlet 332 of the high-position heat-exchanging tube 33. The cooling end working fluid 82 is disposed in the water-cooling tower 93 and the high-position heat-exchanging tube 33.

As discussed above, in the data center and the phase change coolant distribution unit thereof in one embodiment of the disclosure, the use of dense pipelines is replaced by phase change of the phase change fluid in the heat-exchanging chamber. That is, the heat-source pump only spending a small amount of energy is enough to drive the heat-source end working fluid, thus saving overall energy consumption. In addition, the boiling point of the heat-source end working fluid is higher than the boiling point of the phase change fluid, such that when maintaining the heat sources such as servers, even if the heat-source chamber is opened, the situation, in which the heat-source end working fluid evaporates into vapor and leaks into the atmosphere, will not occur easily.

Although the disclosure is disclosed in the foregoing embodiments, it is not intended to limit the disclosure. All variations and modifications made without departing from the spirit and scope of the disclosure fall within the scope of the disclosure. For the scope defined by the disclosure, please refer to the attached claims.

What is claimed is:

1. A phase change coolant distribution unit, comprising:
a heat-exchanging chamber;
a low-position heat-exchanging tube, disposed through the heat-exchanging chamber, wherein at least one portion of the low-position heat-exchanging tube is located in the heat-exchanging chamber;
a high-position heat-exchanging tube, disposed through the heat-exchanging chamber, wherein at least one portion of the high-position heat-exchanging tube is located in the heat-exchanging chamber, and a position of the high-position heat-exchanging tube is higher than a position of the low-position heat-exchanging tube; and
a phase change fluid, disposed in the heat-exchanging chamber.

2. The phase change coolant distribution unit according to claim 1, wherein the low-position heat-exchanging tube is a U-shaped tube or a coiled tube.

3. The phase change coolant distribution unit according to claim 1, wherein the high-position heat-exchanging tube is a U-shaped tube or a bent tube.

4. The phase change coolant distribution unit according to claim 1, wherein the high-position heat-exchanging tube is a heat pipe or a vapor chamber, an evaporation end of the heat pipe or an evaporation end of the vapor chamber is located in the heat-exchanging chamber, and a condensation end of the heat pipe or a condensation end of the vapor chamber is located outside the heat-exchanging chamber.

5. The phase change coolant distribution unit according to claim 4, further comprising a cooling chamber, disposed outside the heat-exchanging chamber, wherein the condensation end of the heat pipe is located in the cooling chamber.

6. The phase change coolant distribution unit according to claim 1, wherein a liquid surface of the phase change fluid is located between the low-position heat-exchanging tube and the high-position heat-exchanging tube, or the high-position heat-exchanging tube passes through the liquid surface, or the low-position heat-exchanging tube and the high-position heat-exchanging tube are located under the liquid surface.

7. The phase change coolant distribution unit according to claim 1, wherein the phase change fluid is water, methanol, acetone, ionic fluid or dielectric fluid.

8. The phase change coolant distribution unit according to claim 1, further comprising a vapor-phase valve, a liquid-phase valve and a pressure relief tank, wherein the liquid-phase valve and the vapor-phase valve are disposed at the heat-exchanging chamber, and the pressure relief tank is connected to the liquid-phase valve and the vapor-phase valve.

9. The phase change coolant distribution unit according to claim 1, further comprising a thermometer, disposed at the heat-exchanging chamber and configured to measure a temperature of the phase change fluid.

10. The phase change coolant distribution unit according to claim 1, further comprising a pressure gauge, disposed at the heat-exchanging chamber and configured to measure a pressure of a vapor-phase portion of the phase change fluid.

11. The phase change coolant distribution unit according to claim 1, further comprising a pressure relief valve, disposed at the heat-exchanging chamber.

12. The phase change coolant distribution unit according to claim 1, further comprising a vacuum valve, disposed at the heat-exchanging chamber.

13. A data center, comprising:
a server rack, comprising:
a heat-source chamber; and
a plurality of heat sources, disposed in the heat-source chamber;
the phase change coolant distribution unit according to one of claims 1-3 and 5-11;
a heat-source end working fluid, disposed in the low-position heat-exchanging tube and the heat-source chamber;
a heat-source pump, disposed between the heat-source chamber and the low-position heat-exchanging tube, wherein the heat-source pump is configured to drive the heat-source end working fluid to flow; and
a water-cooling tower, connected with the high-position heat-exchanging tube.

14. The data center according to claim 13, further comprising a cooling end working fluid and a cooling pump, wherein the cooling end working fluid is disposed in the high-position heat-exchanging tube and the water-cooling tower, the cooling pump is disposed between the water-cooling tower and the high-position heat-exchanging tube, and the cooling pump is configured to drive the cooling end working fluid to flow.

15. A data center, comprising:
a server rack, comprising:
a heat-source chamber; and
a plurality of heat sources, disposed in the heat-source chamber;
the phase change coolant distribution unit according to claim 4;
a heat-source end working fluid, disposed in the low-position heat-exchanging tube and the heat-source chamber; and
a heat-source pump, disposed between the heat-source chamber and the low-position heat-exchanging tube, wherein the heat-source pump is configured to drive the heat-source end working fluid to flow.

16. The data center according to claim 15, further comprising a water-cooling tower, a cooling end working fluid and a cooling pump, wherein the phase change coolant distribution unit further comprises a cooling chamber, the cooling chamber is disposed outside the heat-exchanging chamber, a condensation end of the heat pipe is located in the cooling chamber, the cooling end working fluid is disposed in the cooling chamber and the water-cooling tower, the cooling pump is disposed between the water-cooling tower and the cooling chamber, and the cooling pump is configured to drive the cooling end working fluid to flow.
